(19) United States
(12) Patent Application Publication
(10) Pub. No.: US 2019/0319119 A1
(43) Pub. Date: Oct. 17, 2019

(54) FORMATION OF INSERTED-OXIDE FIN FIELD-EFFECT TRANSISTORS

(71) Applicant: INTERNATIONAL BUSINESS MACHINES CORPORATION, Armonk, NY (US)

(72) Inventors: Juntao Li, Cohoes, NY (US); Kangguo Cheng, Schenectady, NY (US); Peng Xu, Santa Clara, CA (US); Zhenxing Bi, Niskayuna, NY (US)

(21) Appl. No.: 15/950,568

(22) Filed: Apr. 11, 2018

(51) Int. Cl. H01L 29/66; H01L 29/06; H01L 29/423; H01L 29/786; H01L 21/02

(52) U.S. Cl. CPC H01L 29/66742; H01L 29/0673; H01L 29/42392; H01L 29/78651; H01L 29/66553; H01L 21/02603; H01L 21/02532; H01L 21/02192; H01L 29/66545; H01L 29/78696

(57) ABSTRACT

A semiconductor device including an inserted-oxide fin field-effect transistor (iFinFET) includes a substrate and fins formed on the substrate. Each fin includes a stack of layers having alternating dielectric layers and semiconductor layers, including a first dielectric layer formed on the substrate and a first semiconductor layer formed on the first dielectric layer. The device further includes source and drain regions formed along the stack and on the first dielectric layer, and a gate structure formed transversely across the fins.

### BACKGROUND

### Technical Field

The present invention generally relates to semiconductor devices, and more particularly to inserted-oxide fin field-effect transistors (iFinFETs) and methods of forming the same.

### Description of the Related Art

Fin field-effect transistors (FinFETs) have been widely used in mainstream complementary metal-oxide-semiconductor (CMOS) technologies. To enable ultimate gate-length scaling, gate-all-around (GAA) FETs have been developed. Although the GAA FET structure can provide superior electrostatics, it comes with process challenges such as forming spacers and filling gate metal between nanowires.

### SUMMARY

In accordance an embodiment of the present invention, a method for fabricating a semiconductor device including an inserted-oxide fin field-effect transistor (iFinFET) is provided. The method includes forming a stack of layers on a substrate by epitaxially growing alternating dielectric layers and semiconductor layers, including forming a first dielectric layer on the substrate and a first semiconductor layer on the first dielectric layer. The method further includes patterning fins from the stack, recessing the stack to form source/drain regions along the stack and on the first dielectric layer, and forming a gate structure transversely across the fins.

In accordance with another embodiment of the present invention, a method for fabricating a semiconductor device including an inserted-oxide fin field-effect transistor (iFinFET) is provided. The method includes forming a stack of nanosheet layers on a substrate by epitaxially growing alternating dielectric layers including a rare-earth oxide (REO) and semiconductor layers including silicon (Si), including forming a first dielectric nanosheet layer as a thickest layer of the stack on the substrate and a first semiconductor nanosheet layer on the first dielectric layer. The method further includes patterning fins from the stack, recessing the stack to form source/drain regions along the stack and on the first dielectric layer, and forming a gate structure transversely across the fins.

In accordance with yet another embodiment of the present invention a semiconductor device including an inserted-oxide fin field-effect transistor (iFinFET) is provided. The device includes a substrate and fins formed on the substrate. Each fin includes a stack of layers having alternating dielectric layers and semiconductor layers, including a first dielectric layer formed on the substrate and a first semiconductor layer formed on the first dielectric layer. The device further includes source and drain regions formed along the stack and on the first dielectric layer, and a gate structure formed transversely across the fins.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of an alternating semiconductor layer/dielectric layer stack formed during the fabrication of a semiconductor device, in accordance with an embodiment of the present invention;

FIG. 2 is a top-down view of fins patterned during the fabrication of the semiconductor device, in accordance with an embodiment of the present invention;

FIG. 3 is a cross-sectional view through the fins shown in FIG. 2;

FIG. 4 is a top-down view of a dummy gate structure formed in a gate region and spacers formed across the fins during the fabrication of the semiconductor device, in accordance with an embodiment of the present invention;

FIG. 5 is a cross-sectional view through the dummy gate structure after the formation of the dummy gate structure and the spacers shown in FIG. 4;

FIG. 6 is a cross-sectional view through the fins after the formation of the dummy gate structure and the spacers shown in FIG. 4;

FIG. 7 is a cross-sectional view through the dummy gate structure showing a recessing of the stack during the fabrication of the semiconductor device, in accordance with an embodiment of the present invention;

FIG. 8 is a cross-sectional view through the dummy gate structure showing source/drain regions formed during the fabrication of the semiconductor device, in accordance with an embodiment of the present invention;

FIG. 9 is a top-down view of formation of an interlevel dielectric (ILD) and removal of the dummy gate structure during the fabrication of the semiconductor device, in accordance with an embodiment of the present invention;

FIG. 10 is a cross-sectional view through the exposed gate region after the formation of the ILD and the removal of the dummy gate structure shown in FIG. 9;

FIG. 11 is a cross-sectional view through the fins after the formation of the ILD and the removal of the dummy gate structure shown in FIG. 9;

FIG. 12 is a cross-sectional view through the fins showing an undercutting of the dielectric layers of the stack during the fabrication of the semiconductor device, in accordance with an embodiment of the present invention;

FIG. 13 is a top-down view of a formation of a gate structure during the fabrication of the semiconductor device, in accordance with an embodiment of the present invention;

FIG. 14 is a cross-sectional view through the gate structure after the formation of the gate structure shown in FIG. 13;

FIG. 15 is a cross-sectional view through the fins after the formation of the gate structure shown in FIG. 13;

FIG. 16 is a cross-sectional view through the dummy gate structure showing an undercutting of the dielectric layers of the stack after the recessing of the stack shown in FIG. 7 during the fabrication of the semiconductor device, in accordance with an embodiment of the present invention;

FIG. 17 is a cross-sectional view through the dummy gate structure of inner spacers formed after the undercutting of FIG. 16 during the fabrication of the semiconductor device, in accordance with an embodiment of the present invention;

FIG. 18 is a cross-sectional view through the gate structure of the structure shown in FIG. 14 having the inner spacers shown in FIG. 17.

### DETAILED DESCRIPTION

Nanosheet FETs, such as GAA FETs, can reduce problems associated with channel width variations, including undesired variability and mobility loss. However, such nanosheet FETs can come with process challenges. For example, challenges associated with GAA FETs can include forming spacers and filing gate metal between nanowires or nanosheets.

Inserted-oxide FinFETs (iFinFETs) can achieve trade-offs between the process challenges associated with nanosheet FETs (e.g., GAA FETs) and the benefits that they provide. However, one challenge encountered during the fabrication of iFinFETs is the difficulty in forming the semiconductor layer/dielectric layer stack. Some approaches for fabricating iFinFETs require multiple paths of wafer bonding, thereby rendering such approaches impractical for manufacturing iFinFETs.

The embodiments described herein provide for an iFinFET in which dielectric layers are inserted between semiconductor layers in a stack. The dielectric layers can include a high-k dielectric material, which can illustratively be a rare-earth oxide (REO). REOs are oxides formed from rare-earth elements, which include scandium (Sc), yttrium (Y) and the lanthanide elements. The lanthanide elements include cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), terbium (Tb), thulium (Tm) and ytterbium (Yb). The embodiments described herein can be compatible with complementary metal-oxide-semiconductor (CMOS) process flows.

The semiconductor layer/dielectric layer stack can be formed by a single epitaxy step in accordance with the embodiments described herein, and can include a bottom dielectric layer that isolates the device from the substrate. Semiconductor material for source/drain regions can be epitaxially grown from exposed sidewalls of the fins and on the bottom dielectric layer with high quality due to a large crystalline surface area.

The terms “epitaxial growth and/or deposition” means the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSH) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

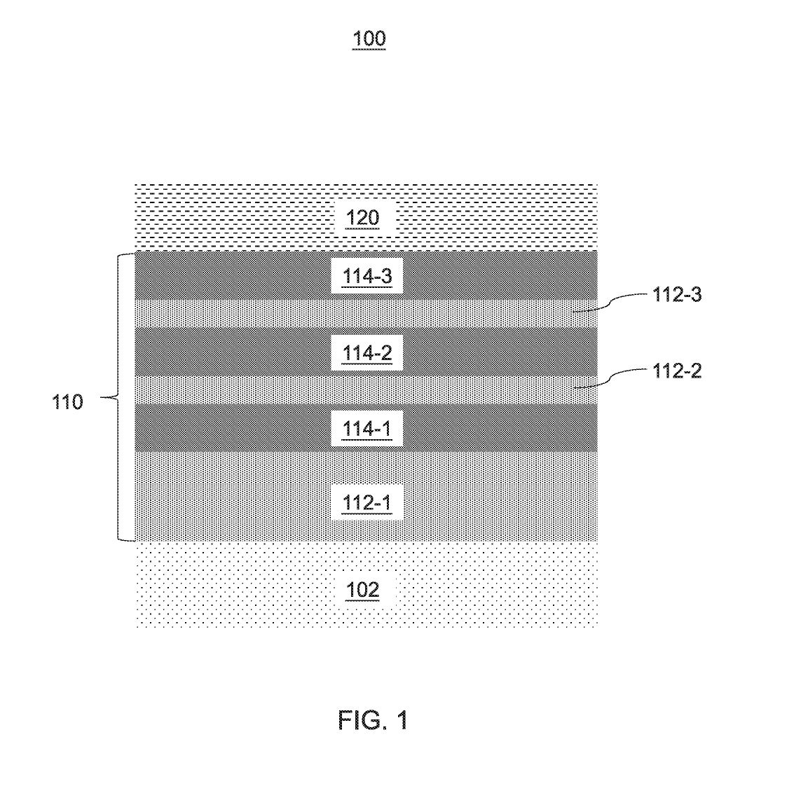

Referring now to the drawings in which like numerals represent the same or similar elements, FIGS. 1-18 depict respective steps of a process flow for fabricating semiconductor devices including an inserted-oxide fin field-effect transistor (iFinFET).

Referring to FIG. 1, a cross-sectional view is provided showing an exemplary semiconductor device 100 having a substrate 102. In one embodiment, the substrate 102 includes Si, although the materials of the substrate 102 are not limiting. The substrate 102 can include any suitable substrate structure, e.g., a bulk semiconductor, a semiconductor-on-insulator (SOI) substrate, etc. In one example, the substrate 102 can include a silicon-containing material. Illustrative examples of Si-containing materials suitable for the substrate can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

As further shown, a stack 110 is formed on the substrate 102 by epitaxially growing alternating dielectric layers and semiconductor layers. The stack 100 can be formed by a single epitaxy step. The epitaxial materials can be grown by solid state epitaxy, or they may be grown from gaseous or liquid precursors. For example, the epitaxial materials may be grown using vapor-phase epitaxy (VPE), molecular-beam epitaxy (MBE), liquid-phase epitaxy (LPE), rapid thermal chemical vapor deposition (RTCVD), metalorganic chemical vapor deposition (MOCVD), ultrahigh vacuum chemical vapor deposition (UHVCVD), low-pressure chemical vapor deposition (LPCVD), limited reaction processing CVD (LRPCVD), e-beam evaporation, or any suitable combination of those processes.

For example, as shown, the stack 110 can includes dielectric layers 112-1, 112-2 and 112-3 and semiconductor layers 114-1, 114-2 and 114-3, with dielectric layer 112-1 being formed on the substrate 102. As shown in FIG. 1, the dielectric layer 112-1 can be thicker than the rest of the layers of the stack 110. In one embodiment, the dielectric layer 112-1 has a thickness ranging from about 30 nm to about 100 nm, the other dielectric layers 112-2 and 112-3 have a thickness ranging from about 2 nm to about 6 nm for each layer, and the semiconductor layers 114-1 through 114-3 have a thickness ranging from about 5 nm to about 10 nm. The layers of the stack 110 can include nanosheets and/or nanowires.

In one embodiment, the semiconductor layers 114-1 through 114-3 include Si. In one embodiment, the substrate 102 includes a silicon substrate with {111} orientation.

The dielectric layers 112-1 through 112-3 can include a high-k dielectric material. In one embodiment, the dielectric layers 112-1 through 112-3 include an REO material. Examples of such REO materials include Gd₂O₃ and Dy₂O₃, although this should not be considered limiting. In one embodiment, the dielectric layers 112-1 through 112-3 include the same REO material. In another embodiment, the dielectric layers 112-1 through 112-3 can include different materials. For example, the dielectric layer 112-1 can include (ErₓNd₁₋ₓ)₂O₃ and the other dielectric layers 112-2 and 112-3 can include Gd₂O₃ and Dy₂O₃.

As further shown, a hardmask (HM) 120 is formed on the stack 110 (e.g., on the semiconductor layer 114-3). The HM 120 can be formed by any deposition process in accordance with the embodiments described herein (e.g., chemical vapor deposition (CVD), and can include any material suitable for use as hardmask material. For example, the HM 120 can include a nitride-containing material, such as a silicon nitride material (e.g., SiN). Other examples of materials that can be used to form HM 120 include silicon oxides, silicon oxynitrides, silicon carbides, silicon carbonitrides, etc. Spin-on dielectrics may also be utilized as a hardmask material including, but not limited to: silsequioxanes, siloxanes, and boron phosphate silicate glass (BPSG).

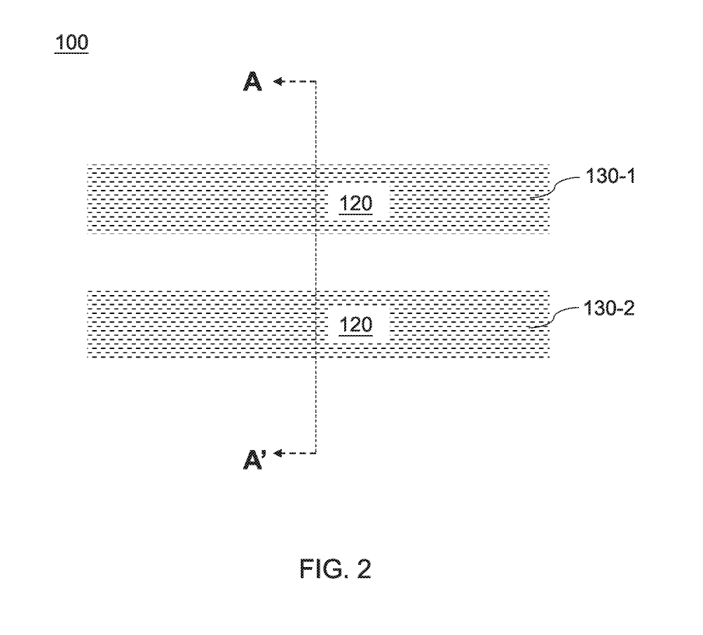

Referring to FIG. 2, a top-down view of the device 100 is provided showing the patterning of fins, including fins 130-1 and 130-2. In a non-limiting embodiment, the lateral width of each of the fins 130-1 and 130-2 can range from about 4 nm to about 10 nm. The fins 130-1 and 130-2 can be formed by any suitable patterning technique, such as lithography followed by a directional etch process (e.g., reactive-ion etching (RIE)). As another example, self-aligned double patterning (e.g., sidewall image transfer), self-aligned quadruple patterning (SAQP), etc. can be used to form the fins 130-1 and 130-2. The two fins 130-1 and 130-2 shown are purely exemplary and, the number of fins should not be considered limiting. In one embodiment, the stack is etched through the HM 120, and the etch stops before etching through the dielectric layer 112-1. The remaining dielectric layer 112-1 between adjacent fins provides electrical isolation between the later formed transistors and the substrate 102.

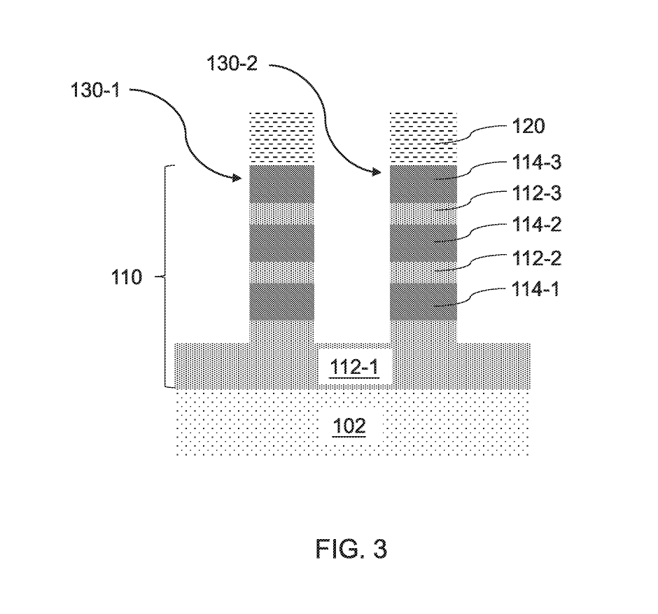

A cross-sectional view of the device 100 taken through line A-A′ is provided with reference to FIG. 3. As shown in FIG. 3, the fins 130-1 and 130-2 include the alternating layers from the stack 110.

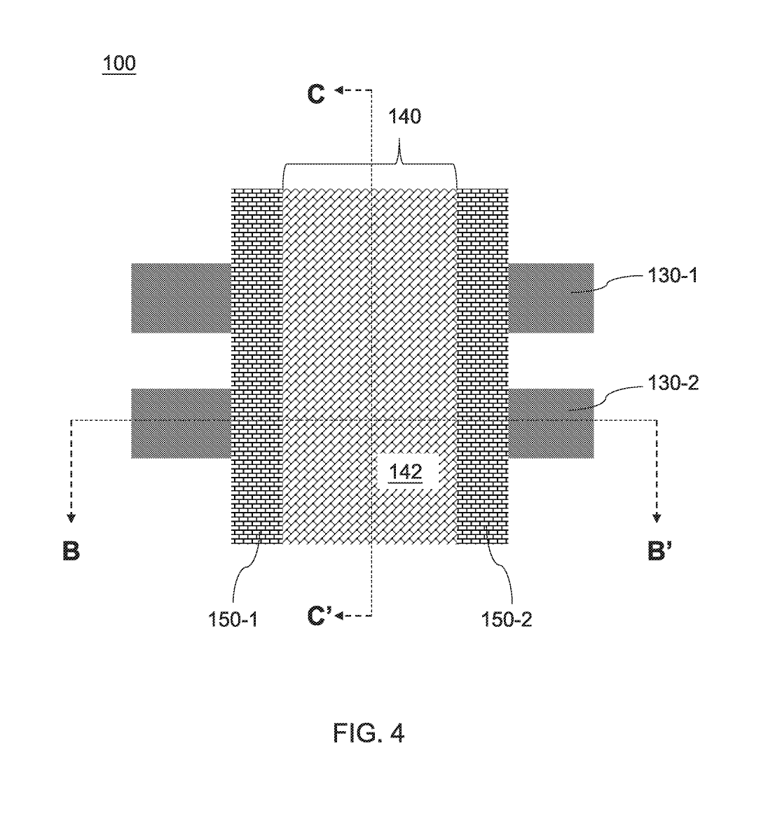

Referring to FIG. 4, a top-down view of the device 100 is provided showing the removal of the HM 120 from the fins formed in FIG. 3, and the formation of a sacrificial or dummy gate structure 140 and spacers 150-1 and 150-2. The dummy gate structure 140 and the spacers 150-1 and 150-2 are formed substantially transverse (e.g., substantially perpendicular) across the fins.

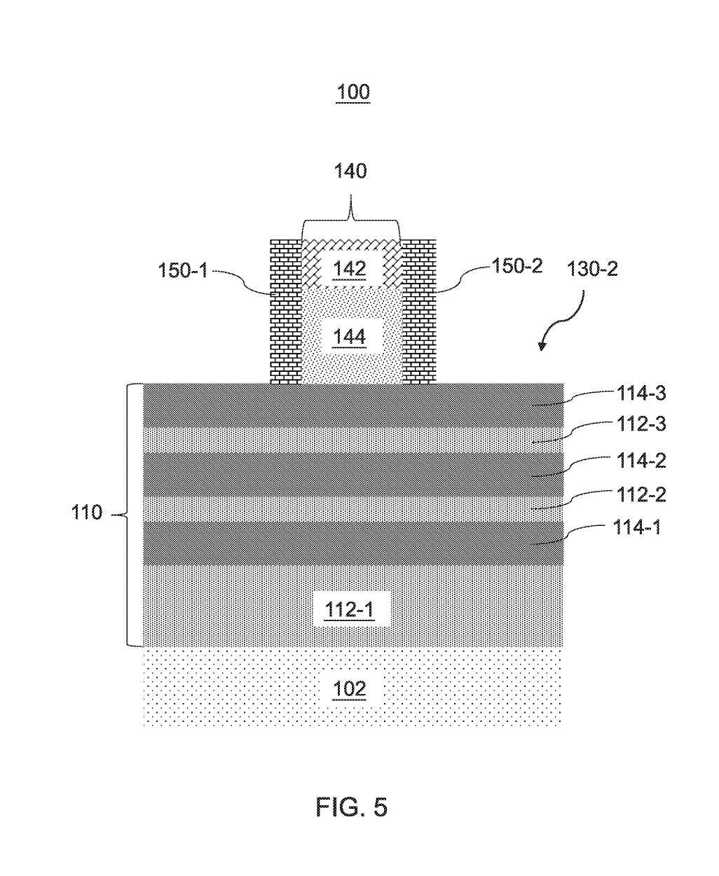

The dummy gate structure 140 can include a cap layer 142 and dummy gate material formed below the cap layer 142 (not visible in the top-down view of FIG. 4). The cap layer 142 can include any suitable material in accordance with the embodiments described herein. For example the cap layer 142 can include a nitride material, such as a silicon nitride material (e.g., SiN). Further details regarding the gate material will be described with reference to FIG. 5.

The spacers 150-1 and 150-2 are gate sidewall spacers that can be formed in direct contact with the dummy gate structure 140. For example, the spacers 150-1 and 150-2 can be formed by depositing a conformal layer of dielectric material, such as oxides, nitrides or oxynitrides, on the dummy gate structure 140, and performing an etch process that removes the conformal layer of dielectric material from all of the surfaces of the dummy gate structure 140 and the fins 130-1 and 130-2, except from the sidewalls of the dummy gate structure 140. Examples of materials that can be used to form the spacers 150-1 and 150-2 include silicon nitride, silicon oxynitride, SiBCN, SiOCN, SiCN, SiOC, etc.

A cross-sectional view of the device 100 taken through line B-B′ of FIG. 4 (through the dummy gate structure) is provided with reference to FIG. 5, which shows the cap layer 142 formed on dummy gate material 144. The dummy gate material 144 can include any suitable material in accordance with the embodiments described herein. For example, the dummy gate material 144 can include a silicon oxide layer around each of the fins 130-1 and 130-2 and polysilicon or amorphous silicon formed on the silicon oxide layer.

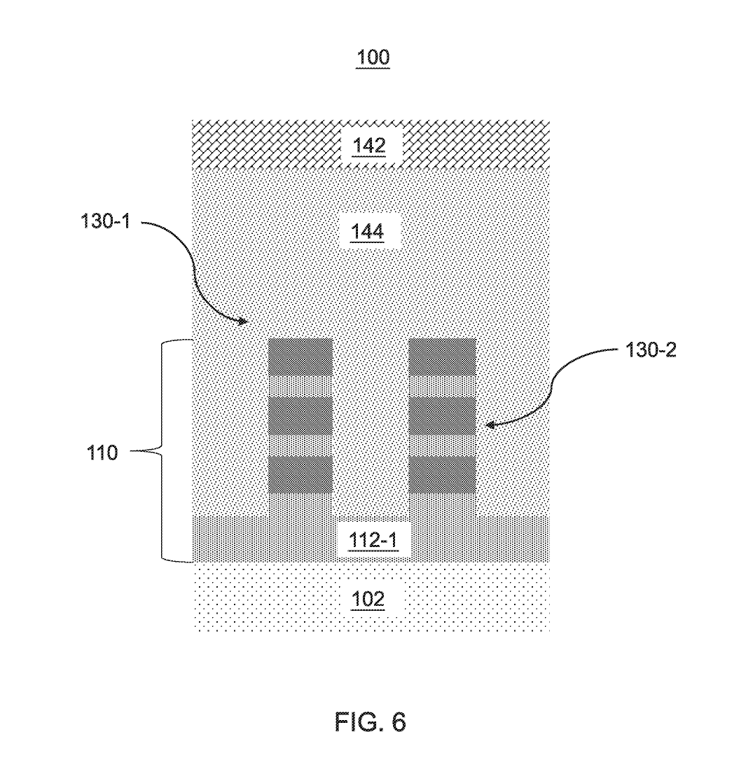

A cross-sectional view of the device 100 taken through line C-C′ of FIG. 4 (through the fins) is provided with reference to FIG. 6.

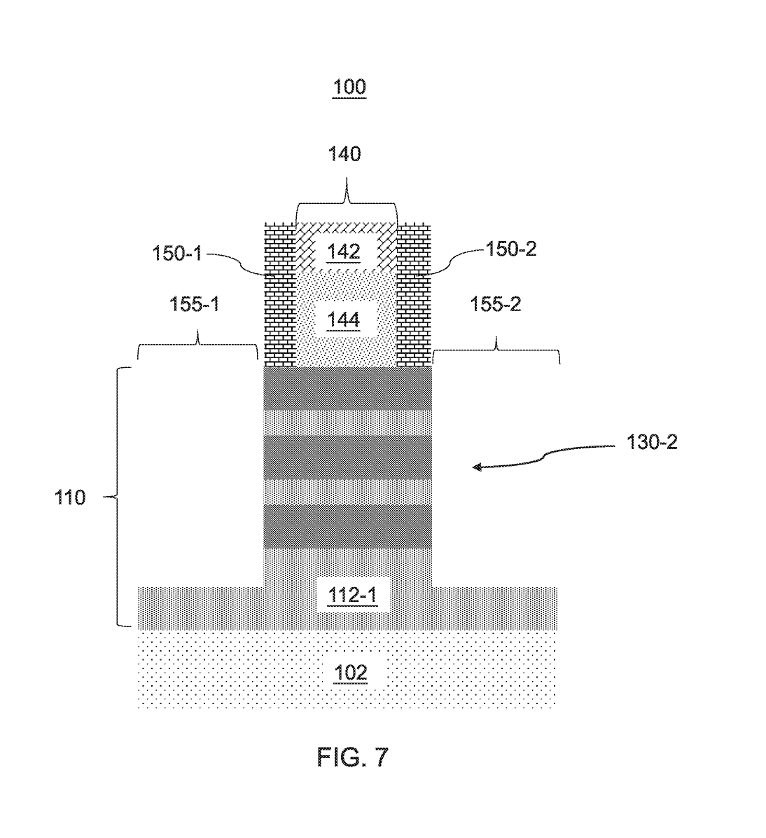

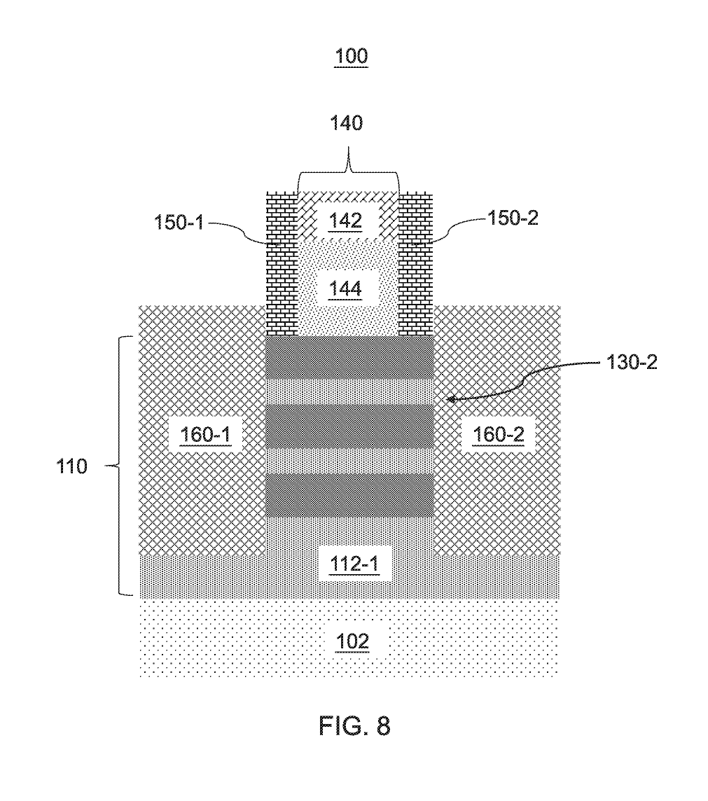

The stacks of each of the fins 130-1 and 130-2 are then recessed to form source/drain regions, and semiconductor material is epitaxially grown in the source/drain regions. For example, with reference to FIG. 7, the stack 110 of fin 130-2 is recessed to form source/drain regions 155-1 and 155-2 along the stack 110 and on the dielectric layer 112-1, and as shown in FIG. 8, semiconductor material 160-1 and 160-2 is epitaxially grown within the source/drain regions 155-1 and 155-2, respectively. The semiconductor material can include any suitable material in accordance with the embodiments described herein.

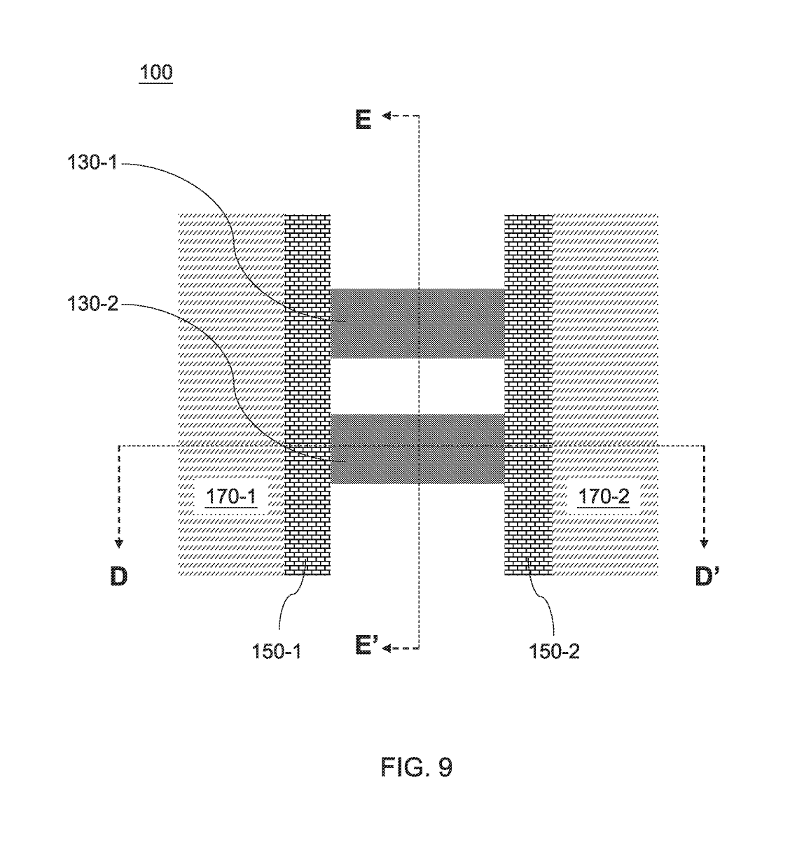

Referring to FIG. 9, a top-down view of the device 100 is provided showing the formation of interlevel dielectric (ILD) layers 170-1 and 170-2, and the removal of the dummy gate structure 140 to expose the gate region. A planarization or polishing process, such as chemical mechanical planarization (CMP), can be performed to smooth the surfaces of the ILD layers 170-1 and 170-2.

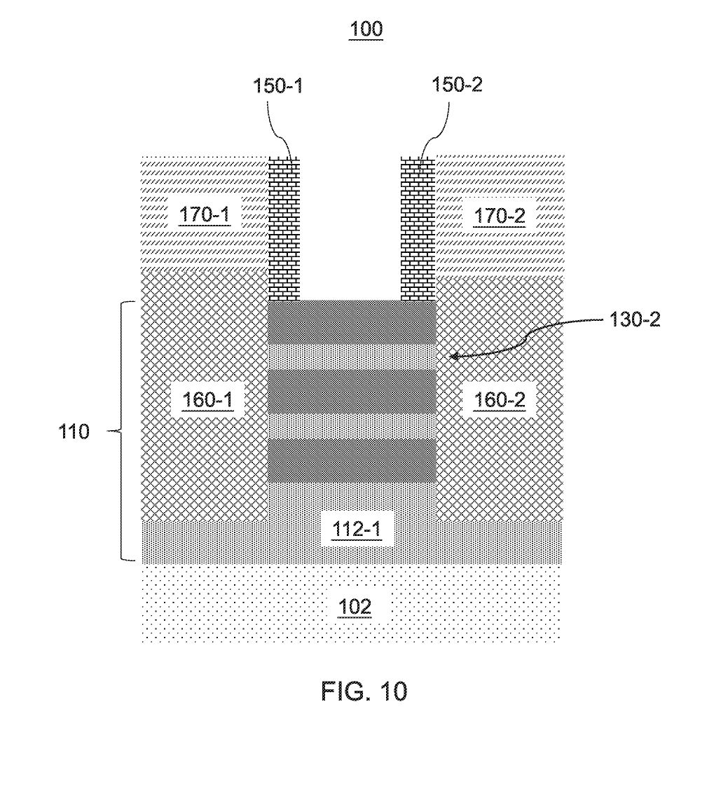

A cross-sectional view of the device 100 taken through line D-D′ of FIG. 9 (through the gate region exposed by the removal of the dummy gate structure 140) is provided with reference to FIG. 10. FIG. 10 shows the ILD layer 170-1 formed on the semiconductor material 160-1 and along the spacer 150-1, and the ILD layer 170-2 formed on the semiconductor material 160-2 and along the spacer 1502, respectively associated with fin 130-2.

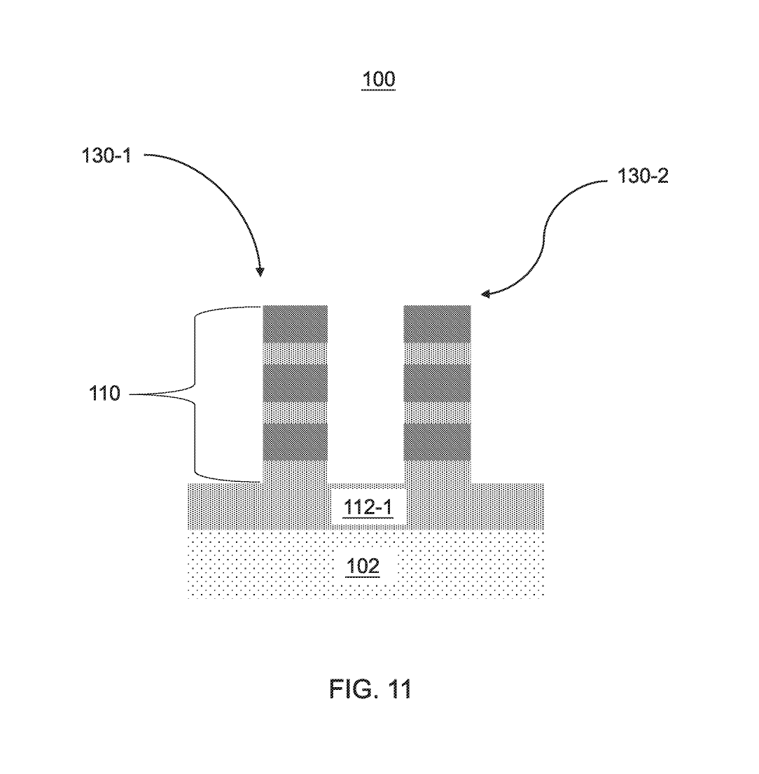

A cross-sectional view of the device 100 taken through line E-E′ of FIG. 9 (through the fins) is provided with reference to FIG. 11. The device 100 as shown in FIG. 11 is similar to the device 100 as shown in FIG. 6, except that the dummy gate structure including the cap layer 142 and the dummy gate material 144 has been removed.

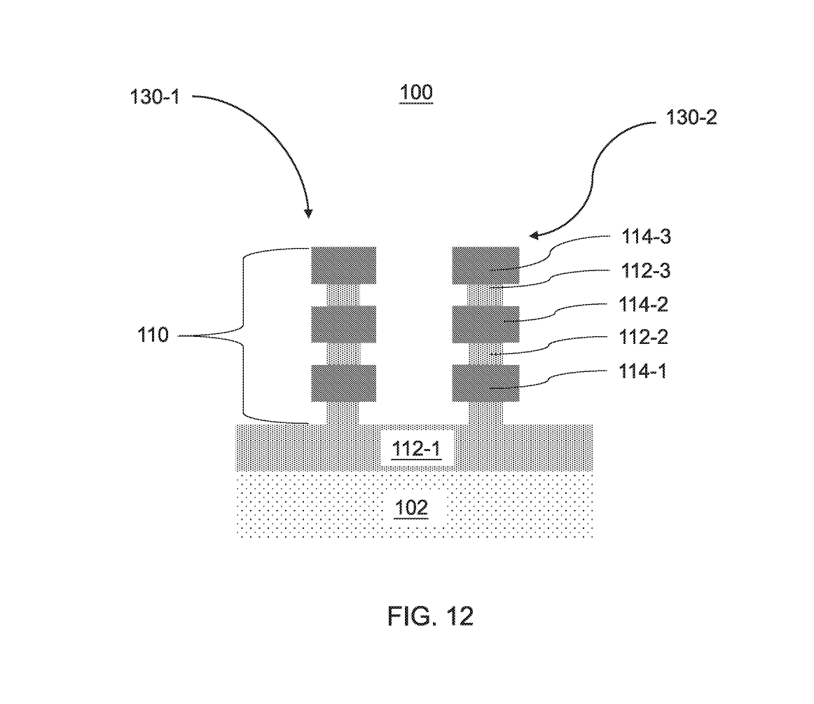

Referring to FIG. 12, in one embodiment, optional indents can be created within the dielectric layers 112-1 through 112-3 to expose top and bottom portions of the semiconductor layers 114-1 through 114-3. The indents can be created by, for example, undercutting the dielectric layers 112-1 through 112-3. This can be done to increase the effective device width and to improve electrostatics.

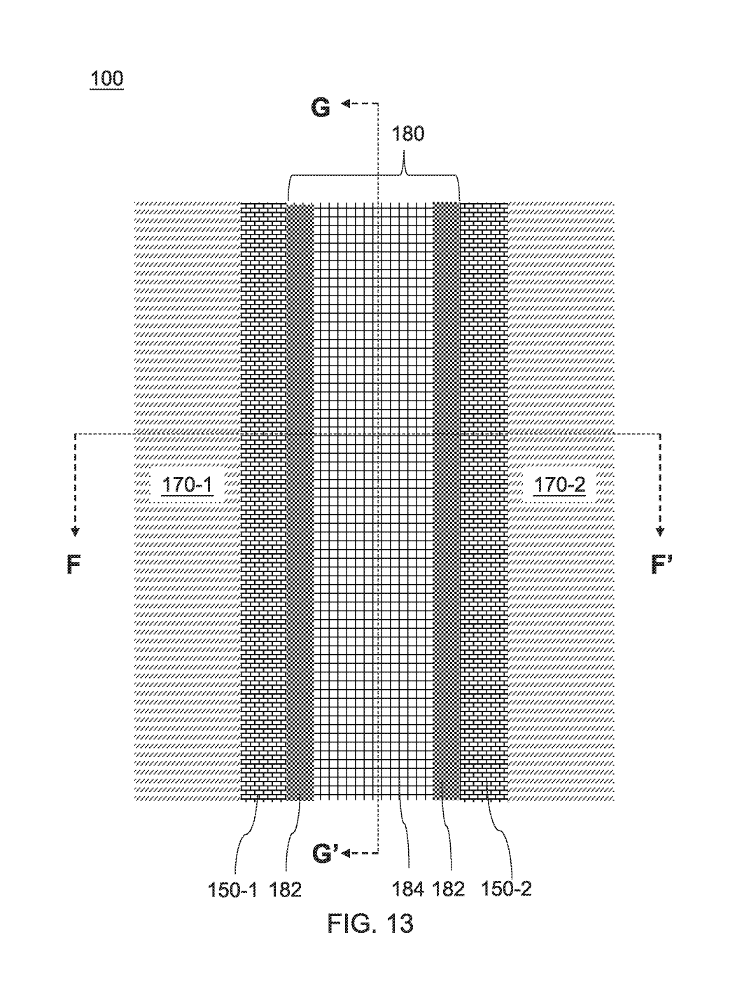

Referring to FIG. 13, a top-down view of the device 100 is provided showing the formation of a gate structure 180 including a gate dielectric 182 and a gate conductor 184. The gate dielectric 182 can include any suitable material in accordance with the embodiments described herein. For example, the gate dielectric 182 can include any suitable dielectric material, including but not limited to silicon oxide, silicon nitride, silicon oxynitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials may further include dopants such as lanthanum, aluminum, magnesium. The gate dielectric 182 can be formed by any suitable process or any suitable combination of multiple processes, including but not limited to, thermal oxidation, chemical oxidation, thermal nitridation, plasma oxidation, plasma nitridation, atomic layer deposition (ALD), chemical vapor deposition (CVD), etc. In some embodiments, the gate dielectric 182 has a thickness ranging from 1 nm to 5 nm, although less thickness and greater thickness are also conceived.

The gate conductor 184 can comprise any suitable material in accordance with the embodiments described herein, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO₂), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials. The gate conductor 184 may further comprise dopants that are incorporated during or after deposition.

In some embodiments, the gate structure 180 may further comprise a work function setting layer (not shown) between the gate dielectric 182 and the gate conductor 184. The work function setting layer can be a work function metal (WFM). The WFM can include any suitable material, including but not limited to a nitride (e.g., titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN)) a carbide (e.g., titanium carbide (TiC) titanium aluminum carbide (TiAlC), tantalum carbide (TaC), hafnium carbide (HfC), etc. In some embodiments, a conductive material or a combination of multiple conductive materials can serve as both the gate conductor 184 and the WFM.

The gate conductor 184 and/or the WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

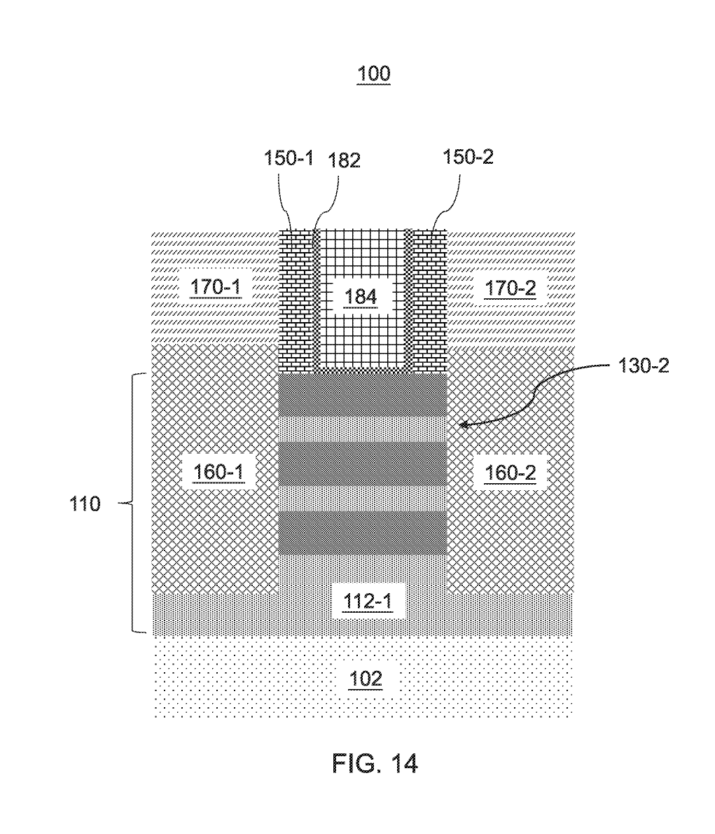

A cross-sectional view of the device 100 taken through line F-F′ of FIG. 13 (through the gate structure 180) is provided with reference to FIG. 14. As shown, the gate dielectric 182 is conformally deposited on the spacers 150-1 and 150-2 and on the stack 100, and the gate conductor 184 is formed within a region defined by the gate dielectric 182.

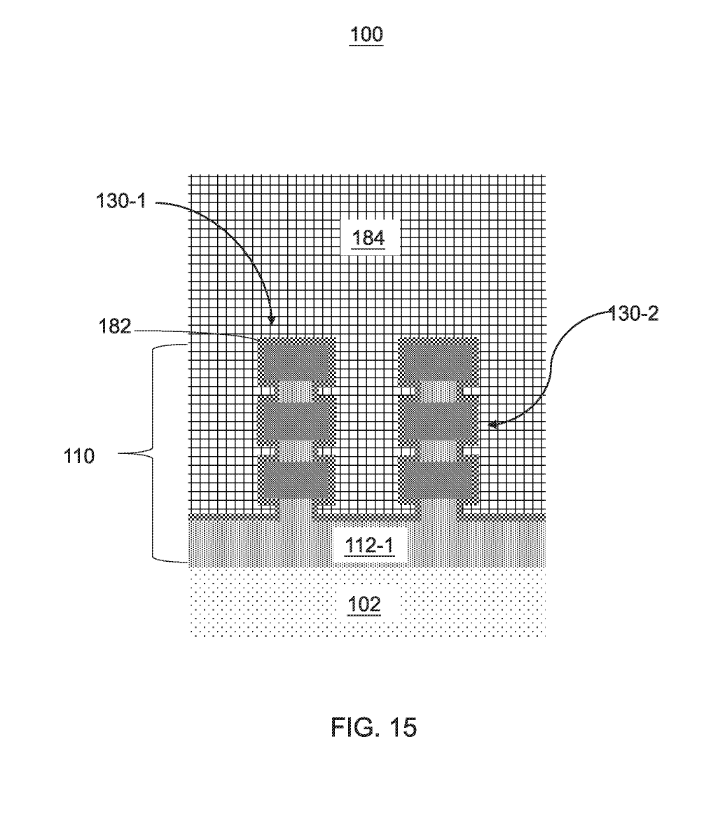

A cross-sectional view of the device 100 taken through the line G-G′ of FIG. 13 (through the fins) is provided with reference to FIG. 15. As shown, the gate dielectric 182 is conformally deposited along the fins 130-1 and 130-2 and the dielectric layer 112-1, and the gate conductor 184 is formed on the gate dielectric material 182. The gate conductor 184 fills in a region defined by the gate dielectric 182, such that the gate structure envelops the fins 130-1 and 130-2 and regions between the fins 130-1 and 130-2.

In an alternative embodiment, after forming the source/drain regions 155-1 and 155-2 as described with reference to FIG. 7, inner spacers can be optionally be formed within the REO layers of the stack within each fin in order to reduce source/drain capacitance. This can be done by laterally undercutting the REO layers of each of the fins to form divots, and filling the divots with inner spacer material. To reduce the source/drain capacitance, the inner spacer material can include any suitable material having a dielectric constant lower than that of the dielectric layers of the stack, in accordance with the embodiments described herein.

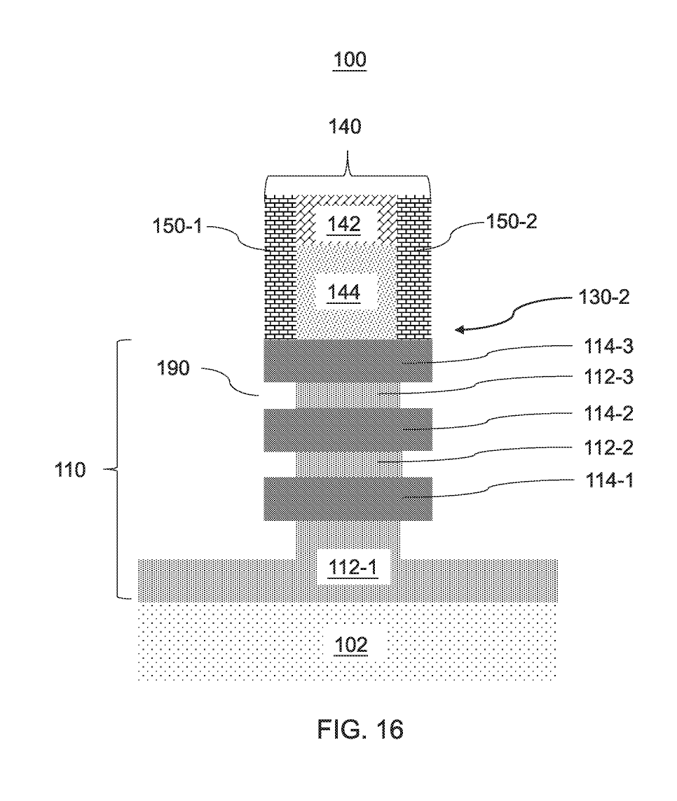

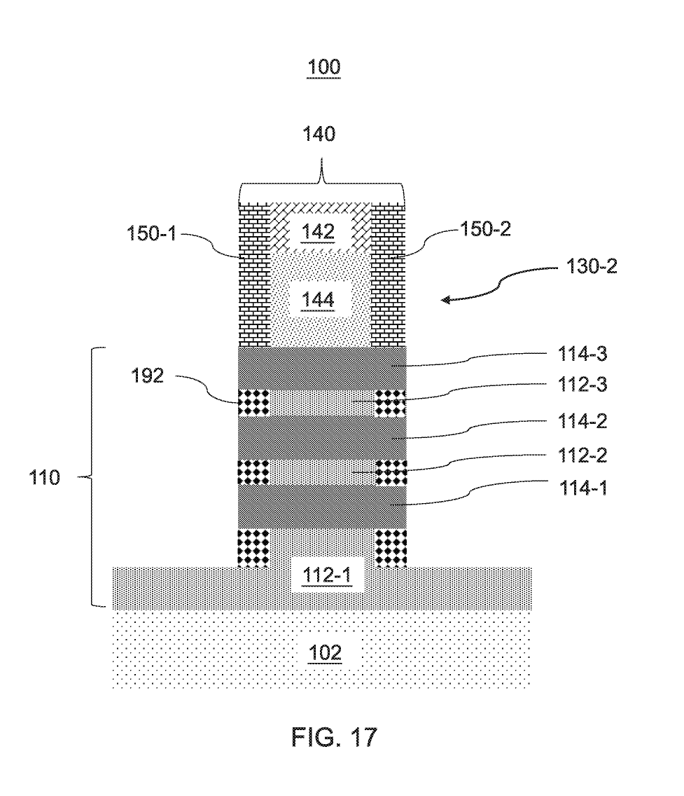

For example, FIG. 16 illustrates a process of laterally undercutting the REO layers 112-1 through 112-3 of the stack 110 of the fin 130-2 to form divots (e.g., divot 190), and FIG. 17 provides a cross-sectional view of the device 100 through the dummy gate structure 140 of forming inner spacers by filling the divots created by the undercutting with inner spacer material (e.g., filling divot 190 with inner spacer material to form inner spacer 192). In one embodiment, the inner spacer material includes a dielectric material with a dielectric constant lower than the dielectric constant of the material of spacers 150-1 and 150-2.

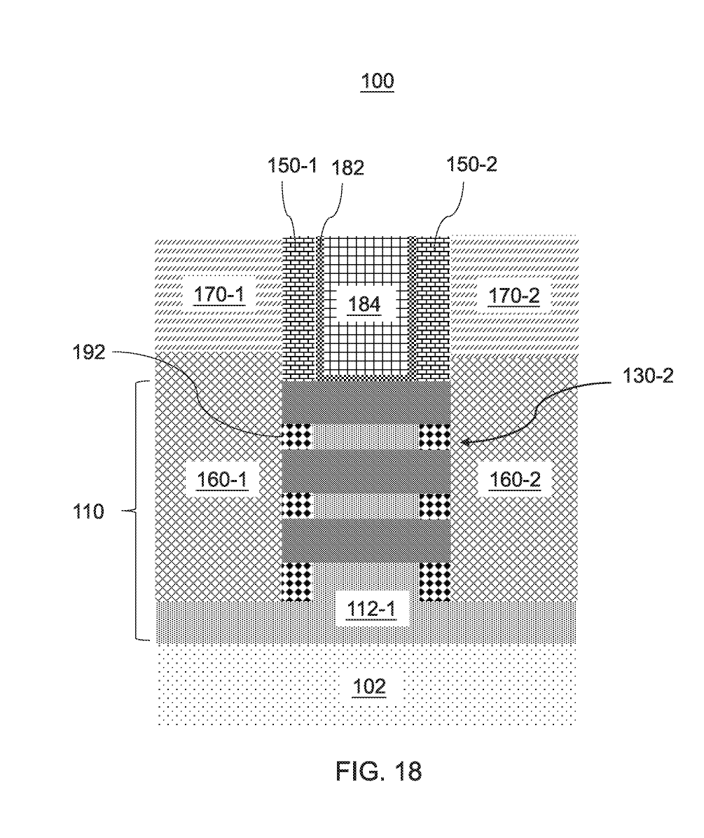

After the inner spacers 190 are formed during the optional inner spacer formation process illustrated in FIGS. 16 and 17, the processes described in FIGS. 8-15 can then be performed to continue the fabrication of the device 100. A cross-section of the resulting device 100 taken through the gate structure 180 is shown in FIG. 18.

Having described preferred embodiments of a semiconductor device and a method of fabricating a semiconductor device (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method for fabricating a semiconductor device including an inserted-oxide fin field-effect transistor (iFinFET), comprising::
forming a stack of layers on a substrate by epitaxially growing alternating dielectric layers and semiconductor layers, including forming a first dielectric layer on the substrate and a first semiconductor layer on the first dielectric layer;
patterning fins from the stack;
recessing the stack to form source/drain regions along the stack and on the first dielectric layer;
forming inner spacers within the dielectric layers after forming the source/drain regions; and
forming a gate structure transversely across the fins.

2. The method of claim 1, wherein each of the dielectric layers includes a rare-earth oxide (REO).

3. The method of claim 1, wherein the stack, is formed in a single epitaxy step.

4. The method of claim 1, of the stack include nanosheets.

5. The method of claim 1, wherein the first dielectric layer is a thickest layer of the stack.

6. The method of claim 1, further comprising forming a dummy gate structure and sidewall spacers along the dummy gate structure prior to recessing the stack to form the source/drain regions.

7. The method of claim 6, wherein forming the gate structure further comprises:
removing the dummy gate structure;
depositing gate dielectric material along the sidewall spacers and the stack; and
forming gate conductive material on the gate dielectric material.

8. The method of claim 1, further comprising creating indents in the dielectric layers to expose top and bottom portions of the semiconductor layers by undercutting the dielectric layers prior to forming the gate structure.

9. (canceled)

10. The method of claim 1, wherein forming the inner spacers comprises laterally undercutting the dielectric layers to form divots, and filling the divots with inner spacer material.

11. A method for fabricating a semiconductor device including an inserted-oxide fin field-effect transistor (iFinFET), comprising:
forming a stack of nanosheet layers on a substrate by epitaxially growing alternating dielectric nanosheet layers including a rare-earth oxide (REO) and semiconductor nanosheet layers including silicon (Si), including forming a first dielectric nanosheet layer on the substrate as a thickest layer of the stack and a first semiconductor nanosheet layer on the first dielectric nanosheet layer;
patterning fins from the stack;
recessing the stack to form source/drain regions along the stack and on the first dielectric nanosheet layer;
forming inner spacers within the dielectric layers after forming the source/drain regions; and
forming a gate structure transversely across the fins.

12. The method of claim 11, wherein the stack is formed in a single epitaxy step.

13. The method of claim 11, further comprising forming a dummy gate structure and sidewall spacers along the dummy gate structure prior to recessing the stack to form the source/drain regions.

14. The method of claim 13, wherein forming the gate structure further comprises:
removing the dummy gate structure;
depositing gate dielectric material along the side all spacers and the stack; and
forming gate conductive material on the gate dielectric material.

15. The method of claim 11, further comprising creating indents in the dielectric nanosheet layers to expose top and bottom portions of the semiconductor nanosheet layers by undercut the dielectric nanosheet layers prior to forming the gate structure.

16. (canceled)

17. The method of claim 11, wherein forming the inner spacers comprises laterally undercutting the dielectric nanosheet layers to form divots, and filling the divots with inner spacer material.

18. A semiconductor device including an inserted-oxide fin field-effect transistor (iFinFET), comprising:
a substrate;
fins formed on the substrate, each fin including a stack of layers having alternating dielectric layers and semiconductor layers, including a first dielectric layer formed on the substrate and a first semiconductor layer formed on the first dielectric layer;
source and drain regions formed along the stack and on the first dielectric layer; and
a gate structure formed transversely across the fins.

19. The device of claim 18, further comprising indents created in each of the dielectric layers to expose top and bottom portions of the semiconductor layers.

20. The device of claim 18, further comprising inner spacers formed within the dielectric layers.
